(19) United States
(12) Patent Application Publication
(10) Pub. No.: US 2024/0289514 A1
(43) Pub. Date: Aug. 29, 2024

(54) AUTONOMOUS DRIVING SIMULATOR

(71) Applicant: TORC Robotics, Inc., Blacksburg, VA (US)

(72) Inventor: Darrell BOWMAN, Blacksburg, VA (US)

(73) Assignee: TORC Robotics, Inc., Blacksburg, VA (US)

(21) Appl. No.: 18/192,522

(22) Filed: Mar. 29, 2023

Related U.S. Application Data
(60) Provisional application No. 63/448,565, filed on Feb. 27, 2023.

(51) Int. Cl. G06F 30/20; B60W 50/02; B60W 60/00

(52) U.S. Cl. CPC G06F 30/20; B60W 50/0205; B60W 60/0051

(57) ABSTRACT

A system can include a driving simulator. The driving simulator can include one or more input devices corresponding to controls of a vehicle; a display; and one or more processors communicatively coupled with the one or more input devices and the display. The one or more processors can be configured to simulate, on the display, an autonomous vehicle driving through a simulated environment in a manual mode based on inputs from the one or more input devices, automatically in an autonomous mode, and transition between manual mode and autonomous mode. The system can include a remote computing device. The remote computing device can be configured to receive an input from a user interface displayed at the remote computing device during a simulation of the autonomous vehicle in the autonomous mode, the input causing a fault in the operation of the autonomous vehicle in the autonomous mode.

### CROSS-REFERENCE TO RELATED APPLICATION

This application claims the benefit of priority to U.S. Provisional Application No. 63/448,565, filed Feb. 27, 2023, the entirety of which is incorporated by reference herein.

### TECHNICAL FIELD

The present disclosure relates generally to autonomous vehicles and, more specifically, to an autonomous driving simulator.

### BACKGROUND

The use of autonomous vehicles has become increasingly prevalent in recent years, with the potential for numerous benefits, such as improved safety, reduced traffic congestion, and increased mobility for people with disabilities. However, with the deployment of autonomous vehicles on public roads, drivers need to adjust to the differences between being behind the wheel of an autonomous vehicle and being behind the wheel of a vehicle that is controlled manually.

Drivers of vehicles, particularly cross-country drivers, can train to drive long distances or specialized vehicles (e.g., semi-trailer trucks) through driving simulators. A driving simulator may involve an application simulating a realistic or otherwise simulated environment while the drivers provide inputs to the application through an input device, such as a steering wheel, break pedal, or acceleration pedal. The drivers can practice driving in different environments through the driving simulator, so when the drivers face the same or similar environments, the drivers may be prepared to make similar driving decisions.

### SUMMARY

Training drivers to drive autonomous vehicles may involve different issues or situations than manual driver training simulations. For example, while autonomous vehicles may involve the vehicles driving without any input from drivers, the same autonomous vehicles may malfunction on the road or face situations that the autonomous vehicles do not recognize or are otherwise not able to handle, such as a malfunctioning streetlight or a slick road. Drivers of autonomous vehicles may need to identify such situations and override autonomous driving mode in autonomous vehicles to keep the vehicles driving safely on the road.

A processor implementing the systems and methods described herein may provide a driving simulator that can train drivers to take control of autonomous vehicles at the right times. The processor can store one or more predetermined paths for a simulated vehicle to drive in a simulated environment. The processor can execute an application to cause the simulated environment to appear on a display or user interface. The processor can update the display or user interface according to a predetermined path of the one or more predetermined paths to cause the user interface to indicate the simulated vehicle is driving automatically according to the predetermined path. While causing the simulated vehicle to drive the predetermined path, the application may be executing in an autonomous mode in which the simulated vehicle is following the predetermined path without any external input. The autonomously mode may simulate a vehicle (e.g., a real-world vehicle) driving autonomously without receiving input from a driver. A user viewing or accessing the driving simulation can provide an input via an input device of the driving simulator to cause the application to change from executing in the autonomous mode to executing in a manual mode in which the simulated vehicle is controlled by user inputs instead of the predetermined path. Thus, the application can simulate a driver taking over an autonomous vehicle driving in autonomous mode to instead control the autonomous car manually.

The driving simulator may train drivers or individuals to identify situations to provide input to change the application from the autonomous mode to the manual mode. For example, the driving simulation may include one or more faults or fault injections at various locations (e.g., defined locations) within the simulated environment. The fault injections may each correspond to a situation in which the correct driving protocol for an autonomous vehicle would be for the driver of the autonomous vehicle to take over operation of the autonomous vehicle to operate the vehicle in manual mode instead of autonomous mode. The fault injections may correspond to different types of adjustments in the predetermined path, such as veering off a road within the simulated environment, sudden breaks, defined steering wheel turns, etc. The processor can determine when the simulated vehicle reaches a location that corresponds to a fault injection while the application operates in the autonomous mode (e.g., follows the predetermined path within the simulated environment). The processor can adjust the predetermined path according to the fault injection to cause the simulated vehicle to travel the adjusted predetermined path. The individual accessing or using the driving simulation can identify the adjustment and provide an input into an input device, thus causing the application to execute in the manual mode instead of the autonomous mode (e.g., cause the application to stop causing the simulated vehicle to drive the predetermined path and instead drive based on inputs from input devices). By simulating fault injections, the simulation can prepare drivers of autonomous vehicles for what to do in instances in the real world that are similar to the fault injections.

To make a driving simulation more realistic, the driving simulator can have or include a housing that is shaped similar to or the same as a cabin of a semi-trailer truck or another vehicle being simulated. The cabin can include the components a standard cabin of a semi-trailer truck would include, such as two seats, seatbelts for the seats, a dashboard, a steering wheel, a break pedal, an acceleration pedal, a rearview mirror, two side mirrors, side windows, and a window at the front of the housing. The different windows can operate as displays for the simulation to increase immersion of the driver into the simulated environment. In some cases, the cabin can be surrounded by a display that depicts the simulated environment. The processor executing the application for the simulation can be located within the housing or be external from the housing. The steering wheel, the break pedal, and the acceleration pedal can each operate as input devices for controlling the simulated vehicle within the simulated environment as well as for changing the mode of execution of the application from the autonomous mode to the manual mode. For example, a driver accessing the simulation can move the steering wheel or press down on one of the pedals to cause the application to change modes from the first mode to the second mode and control the simulated vehicle with the steering wheel and the pedals.

In at least one aspect, the present disclosure describes a driving simulator. The driving simulator can include one or more input devices corresponding to controls of a vehicle; a display; and one or more processors communicatively coupled with the one or more input devices and the display. The one or more processors can be configured to store, in memory, a predetermined path for a simulated vehicle to travel in a simulated environment, the predetermined path indicating one or more trajectories for the simulated vehicle within the simulated environment; execute an application to cause the simulated environment to appear on the display in a autonomous mode in which the application is configured to simulate the simulated vehicle driving by updating the display over time according to the predetermined path; receive an input from at least one of the one or more input devices; and responsive to receiving the input, change the mode of the application from the autonomous mode to a manual mode in which the application is configured to update the display according to inputs from the one or more input devices.

In another aspect, the present disclosure describes a system. The system can include a driving simulator. The driving simulator can include one or more input devices corresponding to controls of a vehicle; a display; and one or more processors communicatively coupled with the one or more input devices and the display. The one or more processors can be configured to simulate, on the display, an autonomous vehicle driving through a simulated environment in a manual mode based on inputs from the one or more input devices, automatically in an autonomous mode, and transition between manual mode and autonomous mode; and a remote computing device, the remote computing device configured to receive an input from a user interface displayed at the remote computing device during a simulation of the vehicle in the autonomous mode, the input causing a fault in the operation of the vehicle in the autonomous mode.

In another aspect, the present disclosure describes a method. The method can include simulating, by a processor on a display, an autonomous vehicle driving through a simulated environment in a manual mode based on inputs from one or more input devices corresponding to controls of a vehicle, automatically in an autonomous mode, and transition between manual mode and autonomous mode; and receiving, by a remote processor, an input from a user interface displayed by the remote processor during a simulation of the autonomous vehicle in the autonomous mode, the input causing a fault in the operation of the autonomous vehicle in the autonomous mode.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 is a block diagram of a system for autonomous driving simulation, according to an embodiment.

FIG. 2 is a block diagram of a system for autonomous driving simulation, according to an embodiment.

FIG. 3A is a method for autonomous driving simulation, according to an embodiment.

FIG. 3B is a method for autonomous driving simulation, according to an embodiment.

FIG. 4 depicts a cabin of a semi-trailer truck, according to an embodiment.

FIGS. 5A-5B depict different views of an autonomous driving simulator, according to an embodiment.

FIG. 6 is a perspective view of a dashboard of an autonomous driving simulator, according to an embodiment.

FIG. 7 is a perspective view of an autonomous driving simulator, according to an embodiment.

FIG. 8 is a perspective view of a display device of an autonomous driving simulator, according to an embodiment.

FIG. 9 is a perspective view of the inside of a cabin of an autonomous driving simulator, according to an embodiment.

FIG. 10 depicts an overhead view switch of an autonomous driving simulator, according to an embodiment.

FIG. 11 depicts a training scenario of an autonomous driving simulator, according to an embodiment.

FIG. 12 depicts an overhead view of a training scenario of an autonomous driving simulator, according to an embodiment.

FIG. 13 depicts an overhead view of a training scenario of an autonomous driving simulator, according to an embodiment.

FIG. 14 depicts an overhead view of a training scenario of an autonomous driving simulator, according to an embodiment.

FIG. 15 depicts an overhead view of a training scenario of an autonomous driving simulator, according to an embodiment.

FIG. 16 depicts an automatic driving simulator status light of an autonomous driving simulator, according to an embodiment.

FIG. 17 depicts audio signals of an automatic driving simulator, according to an embodiment.

FIG. 18 depicts a plan view of a driving simulator, according to an embodiment.

### DETAILED DESCRIPTION

The following detailed description describes various features and functions of the disclosed systems and methods with reference to the accompanying figures. In the figures, similar components are identified using similar symbols, unless otherwise contextually dictated. The exemplary system(s) and method(s) described herein are not limiting and it may be readily understood that certain aspects of the disclosed systems and methods can be variously arranged and combined, all of which arrangements and combinations are contemplated by this disclosure.

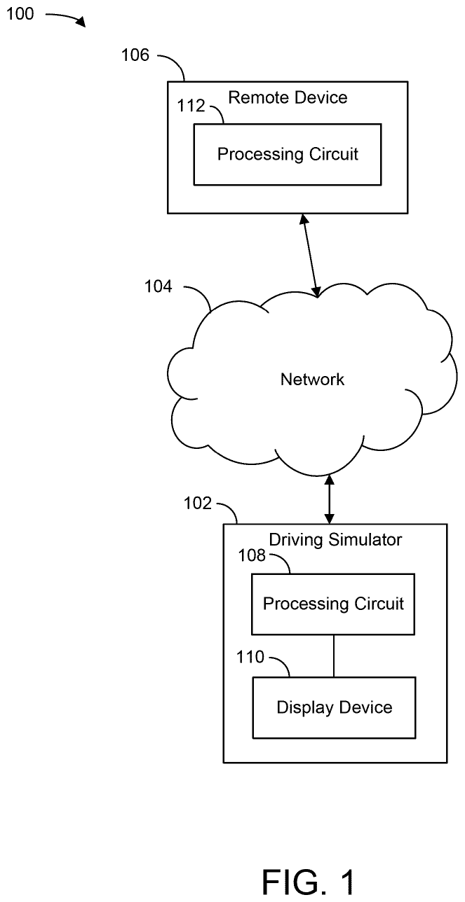

Referring now to FIG. 1, a block diagram of a system 100 for autonomous driving simulation is shown, according to an embodiment. The system 100 may include a driving simulator 102, a network 104, and a remote device 106, in some embodiments. The driving simulator 102 may communicate with the remote device 106 over the network 104. As described herein, the system 100 may be a system for training drivers of autonomous vehicles to identify scenarios or instances to take control of driving autonomous vehicles driving in an autonomous mode.

The driving simulator 102 can include a processing circuit 108 and a display device 110. The processing circuit 108 may communicate with the display device 110 to display a user interface at the display device 110. The driving simulator 102 may process and display an application (e.g., a driving simulator application) via the processing circuit 108 and the display device 110, respectively. The application can be an autonomous vehicle simulation application configured to generate a simulated environment and a simulated vehicle driving within the simulated environment. The processing circuit 108 can store defined or predetermined paths (e.g., driving paths) for the simulated vehicle to drive within the simulated environment over time. The processing circuit 108 can execute the application to cause the simulated vehicle to drive the predetermined paths within the simulated environment.

The network 104 may include any element or system that enables communication between the driving simulator 102, the remote device 106, and the components therein. The network 104 may connect the components through a network interface and/or through various methods of communication, such as, but not limited to, a cellular network, Internet, Wi-Fi, telephone, Lan-connections, Bluetooth, HDMI, or any other network or device that allows devices to communicate with each other. In some instances, the network 104 may include servers or processors that facilitate communications between the components of the system 100.

The processing circuit 108 can display the simulated environment at the display device 110. In doing so, via the application, the processing circuit 108 can simulate a view of a driver within a simulated vehicle traveling through the simulated environment. The processing circuit 108 can simulate the view of the driver of the vehicle according to a predetermined path the simulated vehicle is traveling. The processing circuit 108 can update the display or the user interface being displayed at the display device 110 according to the predetermined path. Accordingly, the processing circuit 108 can execute the application to create an immersive environment simulating the view of a driver behind the steering wheel of an autonomous vehicle.

The driving simulator 102 can include a cabin. The cabin can be in the shape of a semi-trailer truck cabin or other vehicle cabin. The cabin can include components that are similar to or the same as a semi-trailer truck cabin. For example, the cabin can include seats, seatbelts, a rearview mirror, side mirrors, a steering wheel, a brake pedal, an acceleration pedal, a dashboard, etc. Each of the components can be weighted to match or be similar to real-world semi-trailer truck components. Thus, the cabin can be configured to increase immersion of the driving simulator 102 simulation. The processing circuit 108 can be located within the cabin or be external to the cabin.

The display device 110 may be a part of or coupled to the cabin of the driving simulator 102. For example, the display device 110 can be or include a screen at the locations of the windows and/or mirrors of the cabin. For example, each of the front window, the rearview mirror, the side view mirrors, and/or the side windows can be or include a separate display screen. The display screens can be coupled together such that when the processing circuit 108 displays the simulated environment on the display screens, the display screens together display simulated views from the cabin within the simulated environment as if the cabin was in the simulated environment. The processing circuit 108 can determine a view for each display screen of the display device and transmit the views to the respective display screens. In one example, the display screen in the front window can display a view of a road in front of the simulated vehicle, the rearview mirror of the cabin display screen can display a view of the same road behind the simulated vehicle, the display screens at the side windows can display views of opposite sides of the road, and the side mirrors can display simulated views of the road in the simulated environment as would appear in a real-world side mirror. Accordingly, the display device 110 can increase immersion of the driver within the cabin operating within the simulated environment.

The display device 110 can be a display device (e.g., screen) external to the cabin of the driving simulator 102. For example, the display device 110 can include a folding display. The folding display can include two or more folding portions. Each folding portion can include one or more display screens. The folding display can include any number of folding portions. The display screens can be coupled or connected with each other such that when the processing circuit 108 transmits a display for the virtual environment to the display device 110, the display screens can each depict a different view (e.g., a create a continuous view) of the virtual environment. In one example, the display screens can be coupled to depict a panoramic view of the simulated environment. The display screen can fold around all or a portion of the cabin of the driving simulator 102. The windows of the cabin may be empty or transparent such that the driver in the cabin can see the different displays.

The display device 110 may display the simulated environment that is generated and/or maintained by the processing circuit 108. The processing circuit 108 may process the simulated environment and send a user interface to the display device 110 to be displayed. The processing circuit 108 can receive inputs from input devices (e.g., the steering wheel, acceleration pedal, brake pedal, etc.) of the driving simulator 102. The processing circuit 108 can process the inputs and update the user interface being displayed at the display device 110 according to the inputs. The processing circuit 108 may communicate with the display device 110 via an HDMI connection such as a wireless HDMI connection (e.g., WiFi, HDMI wireless, etc.) or a wired HDMI connection.

The remote device 106 can communicate with the driving simulator 102. The remote device 106 can communicate with the driving simulator 102 over the network 104. The remote device 106 can transmit signals to the driving simulator 102 that cause the driving simulator 102 to begin operation (e.g., begin a simulation). The remote device 106 can also transmit signals to the driving simulator 102 to inject faults into the simulation. Faults can be adjustments to a predetermined path of a vehicle. Faults can be referred to as fault injections herein. The faults can each cause a fault in the operation of the simulated vehicle, such as a change in the predetermined path the simulated autonomous vehicle is driving, a change in configuration of the input devices of the driving simulator 102 (e.g., an errant spinning of the steering wheel 118), or another fault. The remote device 106 can inject faults into the simulation by inserting faults at defined locations within the simulated environment such that when the simulated vehicle of the simulated environment reaches the locations, the processing circuit 108 will identify the faults and adjust the predetermined path.

The remote device 106 can insert the faults into the simulated environment in real-time. The remote device 106 can insert such faults during a simulation of an autonomous vehicle driving through a simulated environment. The remote device 106 can insert the faults into the simulated environment by transmitting an identification of the faults to the driving simulator 102 and causing the driving simulator 102 to retrieve the sets of code that correspond to the identifications and changing operation of the simulated vehicle according to the faults. The remote device 106 can insert such faults while the simulated autonomous vehicle is in autonomous mode. The driving simulator 102 can receive the identifications of the faults, retrieve the sets of code that correspond with the identifications, and adjust operation of the simulated vehicle (e.g., the simulated autonomous vehicle) according to the faults. The remote device 106 can insert any number of faults of any type into the simulated environment over the course of a single simulation. A trainer may inject such faults into the simulated environment to train an individual using the driving simulator 102 to more quickly or accurately take control of an autonomous vehicle when the autonomous vehicle begins to operate dangerously or out of control.

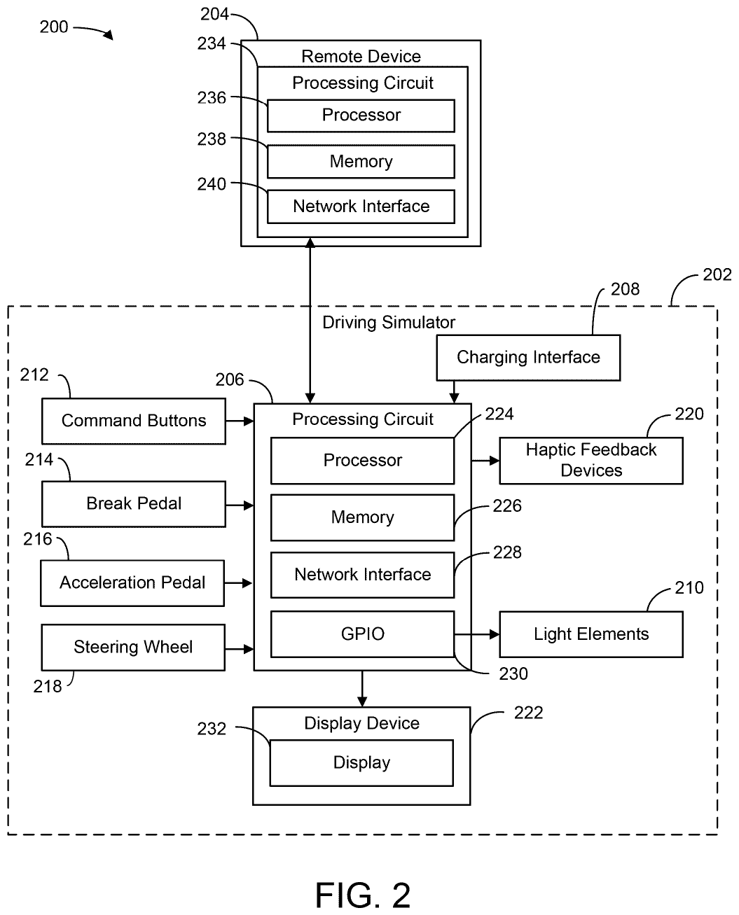

Referring now to FIG. 2, a block diagram of a system 200 for autonomous driving simulation, according to an embodiment. The system 200 can be the same as or similar to the system 100, shown and described with reference to FIG. 1. The system 200 is shown to include a driving simulator 202 and a remote device 204. The driving simulator 202 can be the same as or similar to the driving simulator 102. The remote device 204 can be the same as or similar to the remote device 106.

The driving simulator 202 is shown to include a processing circuit 206, a charging interface 208, light elements 210, command buttons 212, a break pedal 214, an acceleration pedal 216, a steering wheel 218, haptic feedback devices 220, and/or a display device 222. As described above, the display device 222 may be coupled to an exterior component of a cabin of the driving simulator 202 or may be a display external from the display device 222. The processing circuit 206 may receive inputs from each of components 210-222, process the inputs, and display and update an output at the display device 222 based on the inputs. In some embodiments, the processing circuit 206 may additionally or alternatively be a part of the display device 222.

To charge or power the driving simulator 202, an operator may connect the driving simulator 202 to a wall outlet via the charging interface 208. The driving simulator 202 may be configured to only operate when plugged in to an external power source, such as a wall outlet, or may include a battery that can be charged through the charging interface 208 to enable the driving simulator 202 to operate when the driving simulator 202 is not plugged in to an external power source. In some cases, once the driving simulator 202 has finished charging, the operator may disconnect the driving simulator 202 from the wall outlet and operate the driving simulator 202 with the power stored in the rechargeable battery. The operator may disconnect the driving simulator 202 from the wall outlet at any time. In some cases, the operator may operate the driving simulator 202 while it is connected to the wall outlet.

The processing circuit 206 can include a processor 224, memory 226, a network interface 228, and/or a general-purpose input/output (GPIO) unit 230, in some embodiments. The processing circuit 206 may be implemented as a general-purpose processor, an application-specific integrated circuit (“ASIC”), one or more field programmable gate arrays (“FPGAs”), a digital-signal-processor (“DSP”), circuits containing one or more processing components, circuitry for supporting a microprocessor, a group of processing components, or other suitable electronic processing components. The processor 224 may include an ASIC, one or more FPGAs, a DSP, circuits containing one or more processing components, circuitry for supporting a microprocessor, a group of processing components, or other suitable electronic processing components. In some embodiments, the processor 224 may execute computer code stored in the memory 226 to facilitate the activities described herein. Memory 226 may be any volatile or non-volatile computer-readable storage medium capable of storing data or computer code relating to the activities. In one example, memory 226 may include computer code modules (e.g., executable code, object code, source code, script code, machine code, etc.) for execution by the processor 224.

The GPIO unit 230 may include internal circuitry with one or more outputs that enable the processor 224 to control and/or power the light elements 210 and any other peripheral component of the driving simulator 202. For example, the GPIO unit 230 may comprise an input serial interface and convert serial data into signals provided to one or more solid state or analog relays enabling or disabling the light elements 210. Such serial data may be obtained from an application executed by the processor 224 (e.g., such as a current mode (e.g., manual driving mode or autonomous driving mode) in which the application is being executed), a remote application executed by a remote computing device, or any other component or remote device.

In some embodiments, the processing circuit 206 may selectively engage, selectively disengage, control, and/or otherwise communicate with the other components of the driving simulator 202. As shown in FIG. 2, the network interface 228 may couple the processing circuit 206 to the display device 222 and/or an external device (e.g., the remote device 204). The processing circuit 206 may be coupled to more or fewer components. For example, the processing circuit 206 may send and/or receive signals from the components of the driving simulator 202 such as the light elements 210, command buttons 212, the break pedal 214, the acceleration pedal 216, the steering wheel 218, the haptic feedback devices 220, and/or the display device 222. The processing circuit 206 may send and/or receive such signals via the network interface 228.

The processing circuit 206 may send signals to the display device 222 to display a user interface on a display 232 of the display device 222. The processing circuit 206 may send such signals via the network interface 228. The network interface 228 may use various wired communication protocols and/or short-range wireless communication protocols (e.g., Bluetooth, near field communication (“NFC”), HDMI, RFID, ZigBee, Wi-Fi, etc.) to facilitate communication with the various components of the driving simulator 202, including the display device 222, and/or the remote device 204. In some embodiments, the processing circuit 206 may be internally coupled (e.g., within or coupled with or to the same housing) to the display device 222 via a tethered HDMI cable located inside a housing of the driving simulator 202 that runs between the processing circuit 206 and the display device 222.

The processing circuit 206 can execute an application to generate a simulated environment to simulate driving an autonomous vehicle. For example, in executing the application, the processing circuit 206 can simulate an autonomous vehicle driving through the simulated environment. The processing circuit 206 can store predetermined paths that each indicate speeds and/or trajectories (e.g., positions, turns, driving directions, and/or speeds) for the simulated vehicle to travel within the simulated environment. The predetermined paths can include vectors indicating a position or direction for the simulated vehicle to travel within the simulated environment. Predetermined paths (e.g., preprogrammed paths) can include driving maneuvers, such as, but not limited to straight-line driving, changing lanes, merging, transitioning through intersections, biasing position in the lane for passing obstacles or traffic, adjusting speeds, etc. Upon executing the application, the processing circuit 206 can retrieve one of the predetermined paths and cause the simulated vehicle to travel through the simulated environment according to the selected predetermined path. The processing circuit 206 can cause the simulated vehicle to follow the predetermined path without any user input to simulate an autonomous vehicle traveling real-world roads without any real-world input. The configuration of the application while causing the simulated vehicle to travel according to the predetermined path can be a first mode.

A user can take control of the simulated vehicle from the autonomous mode of control of the simulated vehicle. The user can do so by selecting or pressing an input button or input device of an autonomous vehicle, such as rotating the steering wheel 218 or by pressing (e.g., actuating) one of the break pedal 214, the acceleration pedal 216, or one of the command buttons 212. Upon selection or pressing of one of the input buttons and/or input devices, the processing circuit 206 can change the state of the application to cause control of the simulated vehicle to transition to a manual mode (e.g., a second mode) in which the user controls the simulated vehicle through inputs into the input devices of the driving simulator 202. The application will not control the simulated vehicle according to the predetermined path while in the manual mode.

The processing circuit 206 may receive inputs from the command buttons 212, the break pedal 214, the acceleration pedal 216, and/or the steering wheel 218 of the driving simulator 202. Examples of command buttons 212 include, but are not limited to, buttons that correspond to different functional buttons of a vehicle (e.g., a turn signal, windshield wipers, an autonomous mode button that can be selected to cause the vehicle to enter into or leave an autonomous mode, headlight control, mirror control, etc.). The break pedal 214 can correspond to a real-world break pedal of a vehicle. For example, an input from the break pedal 214 can cause the simulated vehicle of the simulated environment to slow down or stop within the simulated environment. The acceleration pedal 216 can correspond to a real-world acceleration pedal of a vehicle. For example, an input from the acceleration pedal 216 can cause the simulated vehicle of the simulated environment to accelerate within the simulated environment. The steering wheel 218 can correspond to a real-world steering wheel of a vehicle. For example, the steering wheel 218 can cause the simulated vehicle to change direction within the simulated environment. The processing circuit 206 can receive and interpret inputs from each of the components 212-218 and update the display being shown at the display device 222 according to the input or update a configuration of the application being executed by the processing circuit 206 according to the input.

The haptic feedback devices 220 can include one or more devices that are configured to provide users of the driving simulator 202 with a sense that the users are driving on a real-world road as the users access the driving simulator 202. The haptic feedback devices 220 can include vibrators that vibrate according to signals the vibrators receive from the processing circuit 206 and/or actuators that cause different platforms to move up and down as the simulated vehicle travels through the simulated environment. The processing circuit 206 can control the haptic feedback devices 220 to simulate how a real-world vehicle would feel driving over a similar environment. For example, the processing circuit 206 can cause the vibrators to vibrate when the simulated vehicle travels over a bumpy road or otherwise bumpy terrain. In another example, the processing circuit 206 can cause an actuator to raise a platform of the driving simulator to tilt a housing of the driving simulator 202 upwards when the simulated vehicle is traveling up a hill. The haptic feedback devices 220 can operate in any manner to simulate real-world driving.

The light elements 210 can be different lights of the driving simulator 202. The lights elements 210 can include lights on the dashboard of the driving simulator 202, a light that indicates whether the driving simulator 202 is currently driving in autonomous driving mode, lights that are typically in a semi-trailer truck cabin, etc. The processing circuit 206 can control the light elements 210 such as by turning the light elements 210 on or off or dimming/increasing the brightness of the light elements 210. The lights on the dashboard can include a user interface element that can emulate a real-world dashboard with indicators of speed, gas (or other energy, such as electric or hydrogen), rotations per minute (RPM), current gear, or any other indicators on such a dashboard.

The processing circuit 206 can simulate the simulated vehicle driving through the simulated environment and update the different indicators of the dashboard according to how the simulated vehicle is driving through the simulated environment (e.g., cause the speed and/or RPM shown on the dashboard to match the speed and/or RPM of the simulated vehicle driving through the simulated environment, monitor the distance the simulated vehicle travels through the simulated environment and update the gas according to the traveled distance and/or a miles per gallon the simulated vehicle is configured to have, etc.). The processing circuit 206 can similarly update any other light elements 210 to cause the light elements to simulate a real-world cabin of a semi-trailer truck driving.

The processing circuit 206 can detect the current configuration (e.g., state) of the application generating and/or updating the simulated environment and/or vehicle. The processing circuit 206 can update the light that indicates whether the driving simulator 202 is currently in autonomous driving mode or not. The processing circuit 206 can detect a first mode of the application in which the application is in autonomous mode and the simulated vehicle is driving within the simulated environment according to the predetermined path (e.g., automatically driving through the simulated environment) or a second mode of the application in which the application is in manual mode and the simulated vehicle is driving based on inputs from the devices (e.g., the command buttons 212, the break pedal 214, the acceleration pedal 216, or the steering wheel 218) of the driving simulator 202. The processing circuit 206 can detect the current configuration (or a change in such a current configuration) of the application and update the light according to the detected configuration or change in configuration.

The processing circuit 206 can display one or more views of the simulated environment on the display 232 of the display device 222. The display 232 can be a screen, such as a liquid crystal display (LCD), a light-emitting diode display (LED), plasma, or any other type of screen. For example, the processing circuit 206 can determine the coordinates (e.g., <x,y,z> coordinates) of the simulated vehicle within the simulated environment. The processing circuit 206 can determine an orientation of the simulated vehicle (e.g., a direction in which the simulated vehicle is facing within the simulated environment). Based on the position and/or orientation of the simulated vehicle, the processing circuit 206 can identify the surrounding area of the simulated vehicle within the simulated environment and generate a display depicting the view of the simulated environment. The processing circuit 206 can transmit the display to the display device 222 for display (e.g., on a user interface) on the display 232.

The processing circuit 206 may update the display over time as the driving simulation runs. For example, the simulated vehicle may travel the predetermined path while the application executed by the processing circuit 206 is in autonomous mode. While the simulated vehicle is driving, the processing circuit 206 can continually detect the new position and/or orientation of the autonomous vehicle and generate updated views of the simulated environment according to the newly detected position and/or orientation. The processing circuit 206 can transmit the updated views to the display device 222 as the processing circuit 206 generates the updated views. The display device 222 can deploy the updated views upon receipt of the views from the processing circuit 206.

The remote device 204 can communicate with the processing circuit 206 of the driving simulator 202. The remote device 204 can be a computing device or client device. The remote device 204 can include a processing circuit 234. The processing circuit 234 can include a processor 236, a memory 238, and a network interface 240. The components 234-240 can be similar to the components 206 and 224-228 of the driving simulator 202.

The remote device 204 can communicate with the processing circuit 206 by transmitting or exchanging messages with the processing circuit 206. The remote device 204 can transmit messages to the processing circuit 206 to cause the processing circuit 206 to initiate a simulation. In one example, a user at the remote device 204 can select a button to cause the driving simulator 202 to begin a simulation. The user may do so, for example, as a trainer or driving instructor for an individual accessing or being trained by the driving simulator 202. The user can select the button and the remote device can transmit a signal to the processing circuit 206 to cause the processing circuit 206 to generate a simulated environment and/or simulate a vehicle driving through the simulated environment. In some cases, the user being trained may initiate the simulation by selecting one of the command buttons 212.

The remote device 204 can transmit messages to the driving simulator 202 to inject faults into the simulation being provided by the driving simulator 202. The fault injections can indicate adjustments to the predetermined paths or a state of an input device of the driving simulator 202 (physically turn the steering wheel 218 of the driving simulator 202). The fault injections can correspond to real-world events that may cause a driver of an autonomous vehicle operating in autonomous to take manual control of the autonomous vehicle. Examples of types of such faults include a hard brake (e.g., a break of three meters/second²), a brake for a minimal risk maneuver (MRM) (e.g., a braking event that begins at one meter/second² and increases to three meters/second²), drifting left or right (e.g., turn the steering wheel slightly left or right from the current state of the steering wheel), a lane change overshoot (e.g., perform a lane change to the left or right and then continue going in the same direction without aligning onto the lane), steer left or right (e.g., an eight level fault injection the vehicle suddenly starts steering towards the left or the right, each level can correspond with a different degree of a change in direction), steer left or right and brake (e.g., turn the steering wheel towards the left or right with different levels of aggressiveness (e.g., level three or seven) and simultaneously apply the brake with different levels (e.g., one meter/second² or three meter/second²) of deceleration, steering wheel oscillation (e.g., cyclic rotational motion of the steering wheel (e.g., multiple levels: light, medium, and/or heavy), stopping beyond a stop line (e.g., while approaching a red light at an intersection, the simulated vehicle will stop three meters beyond the stop line), etc.). The fault injections may include any type of fault injection.

The remote device 204 can transmit fault injections to the driving simulator 202 in real-time as the driving simulator 202 is performing a simulation for a user. For example, a user may be training to drive an autonomous vehicle. As the driving simulator 202 maintains the simulated environment and operates the application in autonomous mode (e.g., the first mode), the remote device 204 can transmit a fault injection to the driving simulator 202. The driving simulator 202 can receive the fault injection and adjust the predetermined path in which the vehicle was traveling according to the fault injection. The user may identify the adjustment and select an input button to change the mode of the application to a manual mode (e.g., second mode) in which the simulated vehicle is controlled by manual inputs instead of based on the predetermined path. The remote device 204 can transmit multiple of such fault injections to the driving simulator 202 over the course of the simulation. The fault injections can be of different types. A user of the remote device 204 can select a type of fault injection from a user interface to cause the remote device 204 to transmit a fault injection of the selected type to the driving simulator 202. Thus, the user at the remote device 204 can train the individual using the driving simulator 202 to handle different situations in the real world while driving an autonomous vehicle.

The remote device 204 can transmit fault injections to the driving simulator 202 prior to the driving simulator 202 initiating a simulation for a user. For example, the remote device 204 can transmit fault injections to the driving simulator 202. The remote device 204 can transmit coordinates for each of the fault injections within the simulated environment to the driving simulator 202. The driving simulator 202 can receive the fault injections and coordinates and store fault injections and coordinates in memory. Accordingly, when a simulated vehicle of a simulated environment reaches one of the coordinates of the fault injections while driving a predetermined path, the driving simulator 202 can adjust the predetermined path according to the fault injection associated with the coordinates that the simulated vehicle reached within the simulated environment.

The processing circuit 206 can adjust the mode of the application from the manual mode (e.g., the second mode) to the autonomous mode (e.g., the first mode). The processing circuit 206 can do so responsive to receiving an input from an input button (e.g., a resume button of the command buttons 212) indicating to change the mode. In some cases, the processing circuit 206 will only change the mode from manual mode to autonomous mode responsive to determining the simulated vehicle is at a predetermined location of a lane of a road. For example, upon receiving an input to change the mode of the application, the processing circuit 206 can detect the current position of the simulated vehicle (e.g., a center or other defined location of the simulated vehicle) relative to a lane line and/or a side of a road on which the simulated vehicle is traveling in the simulated environment. The processing circuit 206 can determine a difference between the current position and a defined position (e.g., the middle) of the lane on which the simulated vehicle is driving. The processing circuit 206 can compare the difference to a threshold (e.g., a defined threshold). Responsive to determining the difference exceeds the threshold, the processing circuit 206 may discard the input to change modes and not change modes into autonomous mode. Responsive to determining the difference is less than the threshold, the processing circuit 206 can change modes to autonomous mode.

Responsive to changing modes from a manual mode to an autonomous mode, the processing circuit 206 can control the simulated vehicle within the simulated environment according to a predetermined path. The predetermined path may be the same predetermined path that the processing circuit 206 was using to control the simulated vehicle prior to a change to the manual mode or a different predetermined path. The processing circuit 206 may operate the simulated vehicle according to the predetermined path based on the current location of the simulated vehicle within the simulated environment. For instance, responsive to determining to change modes from the manual mode to the autonomous mode, the processing circuit 206 can identify the current location (e.g., current coordinates) of the simulated vehicle within the simulated environment. The processing circuit 206 can identify the location of the retrieved predetermined path that matches the current location of the simulated vehicle and begin operating the simulated vehicle according to characteristics (e.g., speed and/or trajectories) of the predetermined path at the matching location. The processing circuit 206 may similarly transition or switch between operating the application in manual mode and autonomous driving mode over time as the user of the driving simulator takes control of the simulated vehicle and/or provides an input to change back into autonomous driving mode. In this way, the processing circuit 206 can simulate driving a real-world autonomous vehicle that can transition between driving in autonomous mode and driving in manual mode.

The driving simulator 202 can include speakers. The processing circuit 206 may transmit audio signals to the speakers corresponding to inputs that processing circuit 206 processes while processing the application for the simulation. The audio signals may be associated with the simulation. For example, the audio signals can correspond to different sounds a driver may hear while driving on the road, the current mode in which the simulated vehicle is driving, and/or audible description (e.g., words) of actions the simulated vehicle is taking while driving. The processing circuit 206 may transmit a signal to the speakers to emit sounds typically heard on the road. The speakers can additionally or instead emit audio signals that indicate whether a simulated vehicle is operating in autonomous mode or manual mod

The remote device 204 can control the mode of a simulated vehicle in real-time. For example, the remote device 204 can transmit an identification of the autonomous mode or the manual mode to the processing circuit 206. The remote device 204 can do so while the processing circuit 206 is simulating a vehicle driving through a simulated environment. The remote device 204 can transmit the identification after receiving a selection of the mode at a user interface being displayed on a display of the remote device 204. The processing circuit 206 can receive the identification and change the mode of the simulated vehicle to the mode that corresponds to the received identification. Accordingly, a trainer training a user of the driving simulator 202 can remotely change the manner in which the processing circuit 206 is controlling the simulated vehicle, giving the trainer more control over the training.

The driving simulator 202 can store different driving scenarios in the memory 226 (in a database in the memory 226). Each driving scenario can include a set of code that, upon execution, causes the processing circuit 206 to change the simulated environment to act out the driving scenario of the set of code. For example, a driving scenario can be for a second simulated vehicle to cut in front of a simulated vehicle. The processing circuit 206 can execute the set of code for the driving scenario the processing circuit 206 to change the simulated environment according to the driving scenario, such as by causing a second vehicle to cut in front of a simulated vehicle being operated by a user of the driving simulator 202. The processing circuit 206 can store any number of driving scenarios in the memory 226.

The remote device 204 can cause the driving simulator 202 to simulate different driving scenarios. For example, the driving scenarios can be stored in the memory 226 with identifications (e.g., alphanumeric strings) that separately identify the driving scenarios. A user of the remote device can provide an input at a user interface provided by the remote device 204 selecting a driving scenario. The remote device 204 can receive the input and transmit an identification of the driving scenario that corresponds to the input to the driving simulator 202. The processing circuit 206 of the driving simulator 202 can identify the driving scenario from the memory 226 that corresponds with the identification received from the remote device 204. The processing circuit 206 can execute the set of code that corresponds with the identified driving scenario. The user at the remote device 204 can cause the driving simulator 202 to simulate any number of driving scenarios over the course of a single simulation session.

In some embodiments, the processing circuit 206 can evaluate how the user of the driving simulator 102 reacts to an inserted fault. The processing circuit 206 can evaluate the user's reaction by comparing the characteristics of the user's response to criteria (e.g., difference in time between insertion of a fault and takeover of control, whether the user adequately maneuvered into an adjacent lane after takeover, or any other criteria). The criteria may vary based on the type of the fault.

In some embodiments, the processing circuit 206 can stop the simulation (e.g., pause the simulation such as by stopping the simulated vehicle from moving within the simulated environment and/or showing a pause screen, stopping execution of the application of the simulation, etc.). The processing circuit 206 can stop the simulation responsive to determining a user of the driving simulator 202 did not satisfy a criterion associated with a fault. For example, the processing circuit 206 may determine it took too long (e.g., a time above a threshold) for a user to take over control of the simulated vehicle. Responsive to the determination, the processing circuit 206 can stop the simulation.

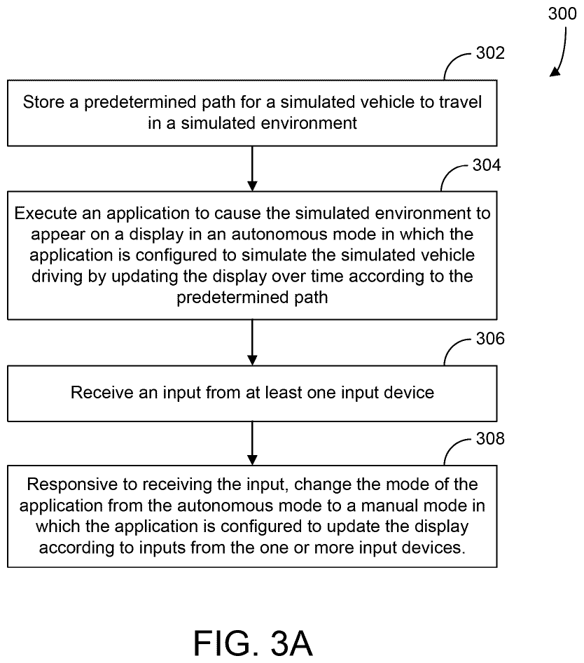

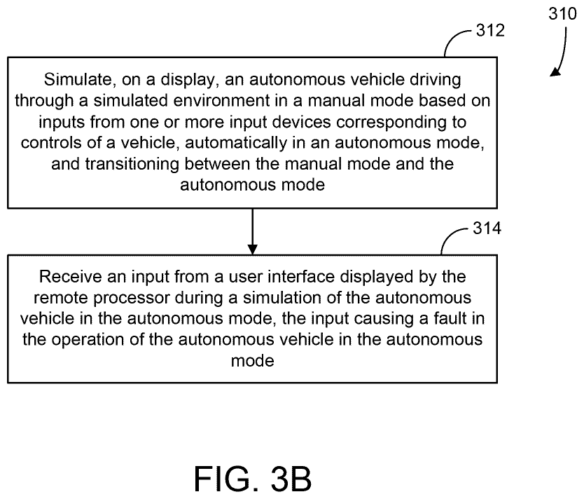

Referring now to FIG. 3A, a method 300 for autonomous driving simulation is shown, according to an embodiment. FIG. 3A shows execution steps of a processor-based method using the system 250, according to some embodiments. The method 300 shown in FIG. 3A comprises execution of steps 302-308. However, it should be appreciated that other embodiments may comprise additional or alternative execution steps, or may omit one or more steps altogether. It should also be appreciated that other embodiments may perform certain execution steps in a different order. Steps discussed herein may also be performed simultaneously or near-simultaneously.

FIG. 3A is described as being performed by a data processing system, such as the processing circuit 206 or the processor 224 depicted in FIG. 2. However, in some embodiments, one or more of the steps may be performed by a different processor, server, or any other computing feature. For instance, one or more of the steps may be performed via a cloud-based service or another processor in communication with the processor of a driving simulator (e.g., an autonomous driving simulator configured to simulate driving an autonomous vehicle).

Using the method 300, the data processing system may operate an autonomous driving simulator that is configured to train drivers to drive real-world autonomous vehicles. For example, the data processing system can simulate an environment that includes a road or other terrain. The data processing can generate a simulated vehicle within the simulated environment. The data processing system can store predetermined paths for the simulated vehicle that indicate locations and/or speed of the simulated vehicle over time as the simulated vehicle travels through the simulated environment. The data processing system can receive fault injections from an external computing device. The fault injections can indicate adjustments to the predetermined paths and/or adjustments to the states, positions, or configurations of input devices of the driving simulator. The data processing system can execute the fault injections as a user views the simulated vehicle autonomously driving through the simulated environment. The user can see the fault injections and press a button to cause the simulated vehicle to take control of the simulated vehicle. The data processing system can iteratively execute such fault injections over time to cause the user to take control of the simulated vehicle for each execution. Accordingly, the data processing system can train the user to take control of real-world autonomous vehicles when the autonomous vehicles the users are driving are affected by real-world scenarios similar to the injected faults.

For example, at step 302, the data processing system stores a predetermined path for a simulated vehicle to travel in a simulated environment. The simulated environment can be a three-dimensional environment that the data processing system generates for a driving simulation of an autonomous vehicle. The simulated environment can include one or more roads including lanes on the roads and other traffic objects (e.g., vehicles on the road, traffic signs, traffic lights, pedestrians, objects in the middle of the road, buildings, foliage, etc.). The simulated environment can include such objects at different coordinates within the simulated environment. The predetermined path can include a speed or velocity and/or trajectory (e.g., a driving path or direction) for a simulated vehicle driving through the simulated environment. The predetermined path can include driving characteristics (e.g., speed, orientation, and/or trajectories) for the simulated vehicle at different locations through the simulated environment. A simulated vehicle driving through the simulated environment according to the predetermined path can follow the speed and/or directions of the predetermined path through the simulated environment.

The data processing system can store the predetermined path in a database (e.g., a relational database). The database can include one or more other predetermined paths. Each predetermined path in the database can be or include different driving directions and/or speeds through the simulated environment. The data processing system can store the predetermined path as one or more vectors each indicating a speed and/or trajectory (e.g., driving direction) at different points in the simulated environment.

The driving simulator can include a housing and a display. The housing can be in the shape of a semi-trailer truck cabin. The display can be external to the housing (e.g., to provide a panoramic view of the simulated environment) or located on the housing (e.g., as a window or mirror of the housing). Thus, the data processing system can increase the immersion of drivers using the driving simulator to better simulate driving an autonomous vehicle, such as an autonomous semi-trailer truck.

At step 304, the data processing system executes an application to cause the simulated environment to appear on a display. The data processing system can execute the application in response to a user input from an input device of a cabin of the driving simulator or from a computer external to the cabin. The user input can be an indication to begin a simulation. The data processing system can execute the application to instantiate the simulated environment, such as in response to the user input. The data processing system can execute the application in an autonomous driving mode (e.g., a first mode) in which the application is configured to simulate a simulated vehicle driving through the simulated environment according to the predetermined path. The data processing system can retrieve the predetermined path from the database and execute the application to cause a simulated vehicle to drive through the simulated environment according to the predetermined path.

The data processing system can simulate the simulated vehicle driving through the simulated environment. The data processing system may do so by displaying a view of the simulated environment from the driver's side of the simulated vehicle. The data processing system can display the view on a user interface of a display device. The data processing system can update the view over time according to the predetermined path as the data processing system causes the simulated vehicle to move throughout the simulated environment, such as driving within a lane of a road of the simulated environment. The data processing system can update the display to simulate the simulated vehicle traveling through the simulated environment.

In some cases, the simulated environment can include one or more fault injections located at one or more locations within the simulated environment. The data processing system can store the locations of the fault injections with coordinates and types of fault in memory. As the simulated vehicle drives around the simulated environment, the data processing system can compare the locations of the simulated vehicle to locations in memory that indicate the locations of the injected faults. Responsive to detecting the simulated vehicle is at a location within the simulated environment that matches a location in memory that corresponds to a simulated fault, the data processing system can adjust the predetermined path according to the type of fault of the location.

The data processing system can adjust the predetermined path according to one or more types of faults. Examples of types of faults include simulating a sudden braking operation, adjusting a position of the steering wheel from a current position of the steering wheel, performing a lane change without aligning into the changed lane, or causing the simulated vehicle to travel past a simulated stop line. The data processing system can adjust the predetermined path in any manner.

The data processing system can insert fault injections into the simulated environment that the data processing system receives in real time. For example, the data processing system can receive, while executing the application to simulate the simulated environment, an identification of a fault injection from a client device or via a user interface. The identification can include a type of the fault injection. Responsive to receiving the identification of the fault injection, the data processing system can determine an adjustment in the pre-determined path. The data processing system can determine the adjustment based on the identification of the fault injection (e.g., based on the type of the fault injection). The data processing system can adjust the predetermined path according to the determined adjustment.

At step 306, the data processing system receives an input from at least one input device. The input device can be a device located within the cabin of the driving simulator, such as a break pedal, an acceleration pedal, or a steering wheel. The input can be generated as a result of a user pressing on the break pedal or the acceleration pedal or spinning the steering wheel. The data processing system can receive the input as the data processing system is executing the application in the autonomous driving mode to cause the simulated vehicle to traverse the simulated environment according to the predetermined path.

The data processing system can evaluate individuals using the driving simulator based on the amount of time it takes for the individuals to provide input to change modes from the autonomous driving mode to the manual driving mode after a fault (e.g., a fault injection) is initiated. For example, upon initiating a fault, the data processing system can begin incrementing a timer. The data processing system can increment the timer every second, for example. The data processing system can increment the timer until the data processing system detects an input that causes the application to execute in the second mode instead of the first mode. The data processing system can identify the value of the timer upon detecting the input as a difference in time between the instantiation of the fault and the input. The data processing system can store the difference in memory.

The data processing system can update user profiles based on the amount of time it takes to provide inputs after instantiating a fault. The user profiles may be data structures (e.g., tables or other types of data structures dedicated to storing data for individual accounts or individuals). For example, the data processing system can identify a profile of the individual using the driving simulator from memory. The data processing system can identify the profile according to login information for the individual's account with the driving simulator or another identifier that the individual inputs into the data processing system. The data processing system can identify differences in time between faults and inputs over the course of the driving simulation or multiple driving simulations. The data processing system can store the differences in the profile for the individual.

Responsive to receiving the input, at step 308, the data processing system changes the mode of the application (e.g., the mode in which the data processing system is executing the application) from the autonomous driving mode (e.g., the first mode) to a manual driving mode (e.g., a second mode). The manual driving mode can be a mode in which the application controls the simulated vehicle based only on inputs from input devices of the driving simulator, not any predetermined path. The data processing system can change the mode of the application to the manual driving mode and cause the simulated vehicle to maintain a state (e.g., speed or direction) unless the data processing system receives inputs from the input devices of the driving simulator to change direction or speeds (e.g., inputs from the break pedal, acceleration pedal, or steering wheel). In some cases, the data processing system may reduce the speed of the simulated vehicle over time similar to a real-world vehicle unless the data processing system receives an input to increase or maintain the speed of the simulated vehicle.

The data processing system can change the mode of the application from the manual mode (e.g., the second mode) to the autonomous driving mode (e.g., the first mode). The data processing system can change the mode from the manual mode to the autonomous driving mode responsive to receiving an input (e.g., a second input) from a button or other input device indicating to change the mode of the application from the manual mode to the autonomous mode. The data processing system can receive the input and automatically change the mode of the application to the autonomous driving mode in response to receiving the input.

In some cases, the data processing system only changes the mode of the application from the manual mode to the autonomous mode in response to determining the simulated vehicle is at a predetermined location (e.g., the middle) within the road on which the simulated vehicle is driving. For example, responsive to receiving the input (e.g., the second input, such as a “resume button”) to change from the manual mode to the autonomous mode, the data processing system can identify the position of the simulated vehicle in the road relative to a defined location on the road. The defined location can be the middle (e.g., a middle line) between a lane line or a side of the road. The data processing system can determine a distance (e.g., 0.2 meters) that the simulated vehicle (e.g., a center of the simulated vehicle) is from the defined location. The data processing system can compare the distance with a threshold (e.g., a predetermined distance). Responsive to determining the distance is lower than the threshold (e.g., the simulated vehicle is within a predetermined distance of the defined location), the data processing system can change the mode of the application from the manual driving mode to the autonomous driving mode. Thus, the data processing system can train users of the driving simulator to use safe driving techniques when transitioning between modes while driving in the real world.

Referring now to FIG. 3B, a method 310 for autonomous driving simulation is shown, according to an embodiment. FIG. 3B shows execution steps of a processor-based method using the system 250, according to some embodiments. The method 310 shown in FIG. 3B comprises execution of steps 312-314. However, it should be appreciated that other embodiments may comprise additional or alternative execution steps, or may omit one or more steps altogether. It should also be appreciated that other embodiments may perform certain execution steps in a different order. Steps discussed herein may also be performed simultaneously or near-simultaneously.

FIG. 3B is described as being performed by a data processing system, such as the processing circuit 206 or the processor 224 depicted in FIG. 2. However, in some embodiments, one or more of the steps may be performed by a different processor, server, or any other computing feature. For instance, one or more of the steps may be performed via a cloud-based service or another processor in communication with the processor of a driving simulator (e.g., an autonomous driving simulator configured to simulate driving an autonomous vehicle).

For example, at step 312, the data processing system simulates, on a display, an autonomous vehicle driving through a simulated environment in a manual mode based on inputs from one or more input devices corresponding to controls of a vehicle, automatically in an autonomous mode, and transitioning between the manual mode and the autonomous mode. At step 314, the data processing system receives an input from a user interface displayed by the remote processor during a simulation of the autonomous vehicle in the autonomous mode, the input causing a fault in the operation of the autonomous vehicle in the autonomous mode.

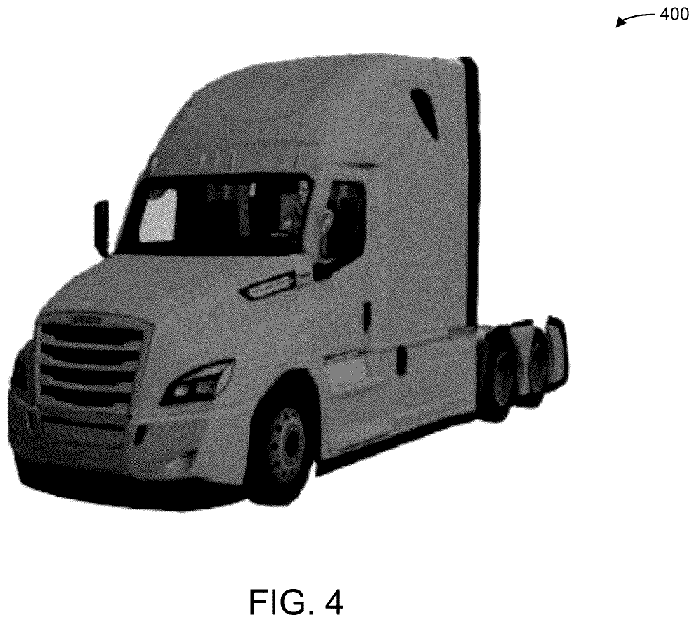

Referring now to FIG. 4, a perspective view of a semi-trailer truck cabin 400 is shown, according to an embodiment. The semi-trailer truck cabin 400 can be a real-world semi-trailer truck cabin. The cabin of the driving simulator 102 and/or 202, shown and described with reference to FIGS. 1 and 2, can be in the same or substantially the same shape as the semi-trailer truck cabin 400.

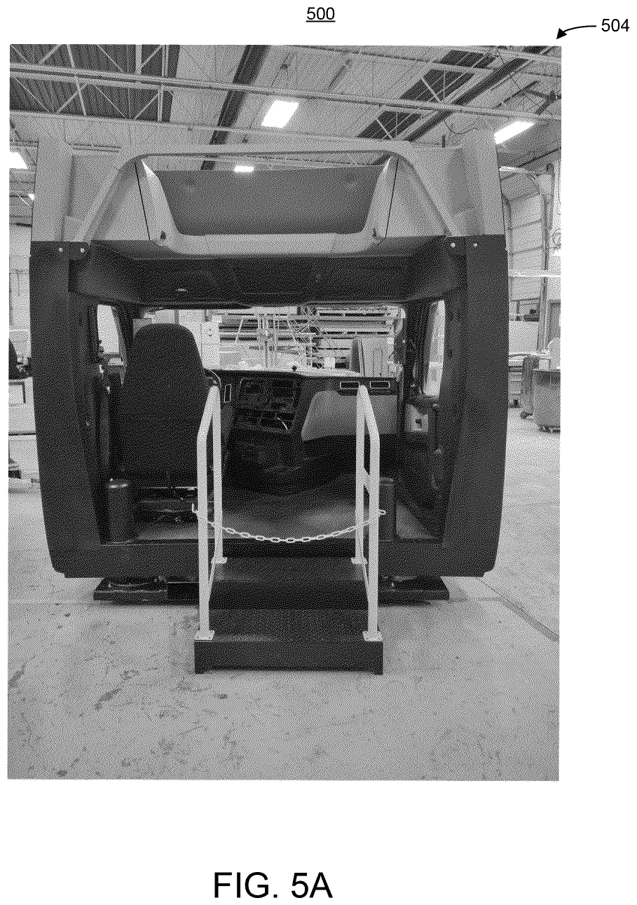

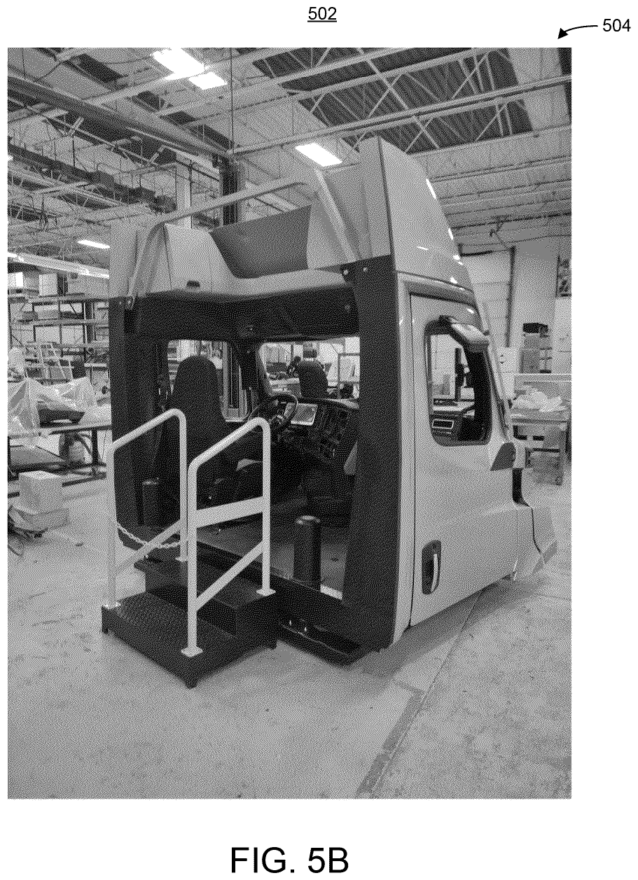

Referring now to FIGS. 5A-5B, perspective views 500 and 502 of a cabin 504 of an autonomous driving simulator are shown, according to an embodiment. The perspective views 500 and 502 illustrate the outside and inside of the cabin 504 of an autonomous driving simulator, such as the driving simulator 102 and/or 202. The cabin can include different input buttons and/or input devices that can provide input to a processor to use to update a driving simulation. The input buttons and/or input devices can correspond to controls of a vehicle (e.g., a real-world vehicle, such as a real-world autonomous driving vehicle). For example, the input buttons and/or input devices of the cabin 504 can be the same or similar to control devices in a real-world vehicle. The cabin can 504 be in the shape of a cabin of a semi-trailer truck, such as the semi-trailer truck cabin 400 shown and described with reference to FIG. 4. The shape and likeness of the cabin 504 and the input devices/input buttons of the cabin 504 can increase the immersion of the driving simulator.

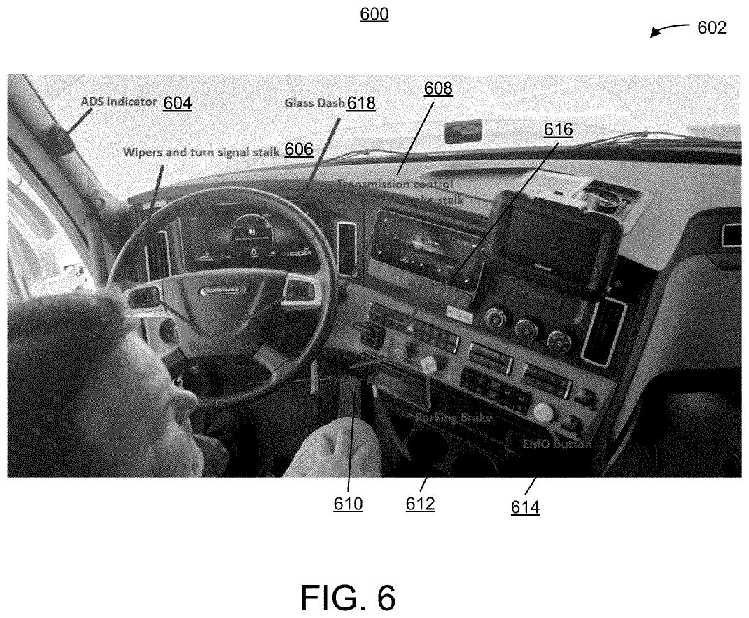

FIG. 6 is a perspective view 600 of a dashboard 602 of an autonomous driving simulator, according to an embodiment. The dashboard 602 can be a dashboard within a cabin of an autonomous driving simulator, such as the driving simulators 102 and/or 202. The dashboard 602 can include an automatic driving system (ADS) indicator 604, a wipers and turn signal stalk 606, a transmission control and engine brake stalk 608, a trailer air switch 610, a parking brake 612, an emergency manual override (EMO) button 614, a hazard button 616, and a glass dash 618. The components 602-618 can each correspond to controls of a vehicle (e.g., a real-world vehicle that drives on the road).

The ADS indicator 604 can indicate whether a vehicle being simulated with the autonomous driving simulator is driving in an autonomous mode (e.g., whether the application simulating the vehicle within a simulated environment is controlling the vehicle in an autonomous mode or a manual mode). The ADS indicator 604 can shine a green light when the simulated vehicle is operating in an autonomous mode and a red light when the simulated vehicle is operating in a manual mode. The ADS indicator 604 can flash red when an autonomous mode is requested (e.g., the user using the autonomous driving simulator has selected a button to enter autonomous mode) but the simulated vehicle has not entered autonomous mode. This may occur, for example, when a user selects a button for autonomous mode but the simulated vehicle is not located at a location on the road within the simulated environment (e.g., within a threshold of a defined location on the road) in which the simulated vehicle can enter autonomous mode. In such cases, the ADS indicator 604 can flash for a defined time period (e.g., five seconds) indicating the simulated vehicle can enter autonomous mode if the simulated vehicle reaches the location on the road. The ADS indicator 604 can stop flashing when the defined time period lapses and the request to enter autonomous mode times out.

The wipers and turn signal stalk 606 can be an input device that provides inputs for controlling a turn signal and/or windshield wipers of a simulated vehicle. The user accessing the driving simulator can change the positions or press buttons on the wipers and turn signal stalk 606 to cause a simulated vehicle to activate windshield wipers and/or a turn signal (e.g., a left or right turn signal).

The transmission control and engine brake stalk 608 can be or include a lever that is mounted on the steering column and allows the user of the driving simulator to easily transition between different modes of operation for the transmission and engine brake. In one position, the transmission control and engine brake stalk 608 can control the transmission of a simulated vehicle, allowing the user to shift between gears and select the appropriate mode for the driving conditions. In another position, the transmission control and engine brake stalk 608 can activate the engine brake, providing additional stopping power of a simulated vehicle.

The trailer air switch 610 can be or include a device that is designed to control the air pressure in a simulated vehicle's braking system. The trailer air switch 610 can allow the user of the driving simulator to easily and quickly adjust the pressure for different driving conditions. The trailer air switch 610 can be mounted on the dashboard of the driving simulator (e.g., a dashboard of the cabin of the driving simulator) and can display the current pressure levels in the brake system.

The parking brake 612 can be a parking brake of the simulated vehicle.

The EMO button 614. The EMO button 614 can be a button that automatically changes the mode of the simulated vehicle from operating in autonomous mode to operating in manual mode. The EMO button 614 can be useful in real-world applications when the autonomous system of an autonomous vehicle malfunctions and does not change back to manual mode upon receiving an input from another input device (e.g., a pedal or a steering wheel) of the autonomous vehicle. The EMO button 614 can be logically and/or physically separate from the system that controls such automatic switches to enable a selection of the EMO button 614 to change the mode of the vehicle from driving in autonomous mode to driving in manual mode. The EMO button 614 can operate similarly for the simulated vehicle of the simulated environment. A user can select or press on the EMO button 614 to cause the application or the simulated vehicle of the driving simulator to transition from autonomous mode to manual mode.

The hazard button 616 can be a button that causes the simulated vehicle to activate the hazard lights of the simulated vehicle.

The glass dash 618 can be a user interface that mirrors or otherwise corresponds to a user interface that can appear on a real-world autonomous vehicle. The glass dash 618 can include different indicators regarding the simulated vehicle, such as available energy or RPMs of a simulated vehicle.

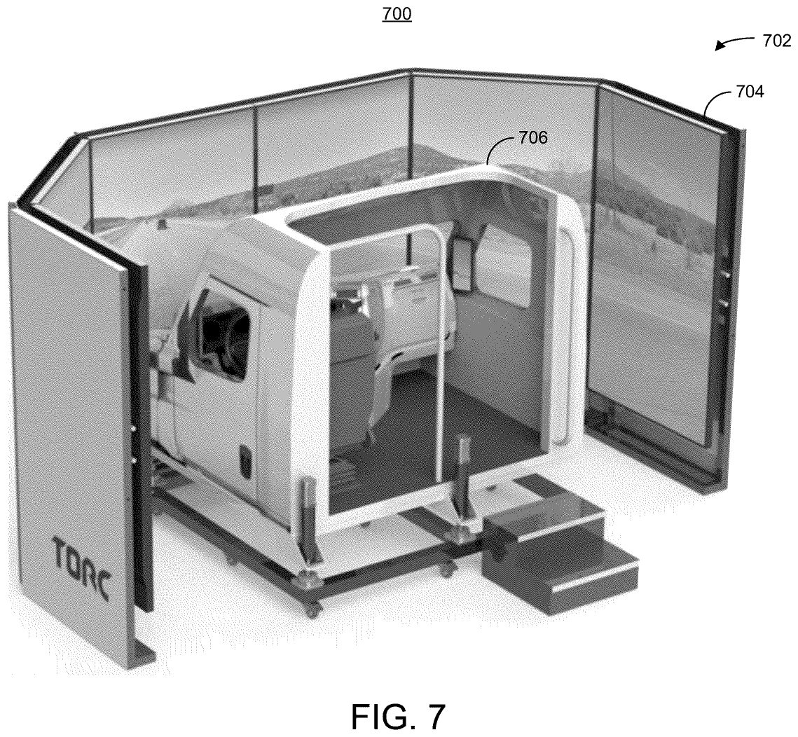

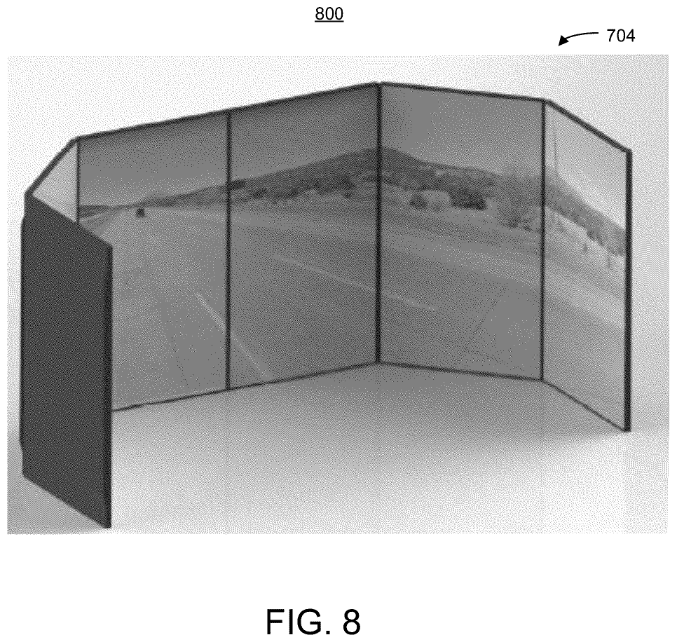

FIG. 7 is a perspective view 700 of an autonomous driving simulator 702, according to an embodiment. The autonomous driving simulator 702 can include a display device 704 and a cabin 706. The autonomous driving simulator 702 can be the same as or similar to the driving simulator 102 and/or the driving simulator 202. The display device 704 can be the same as or similar to the display device 110 and/or the display device 222. The cabin 706 can be the same as or similar to the cabin 504. As illustrated, the display device 704 can include one or more screens (each a display or collectively a display). A processor of the autonomous driving simulator 702 can generate a simulated environment and a view from a simulated vehicle within the simulated environment and display the view on the display device 704. The display device 704 can include multiple screens in a panoramic view to increase the immersion of the simulated environment. FIG. 8 is a perspective view 800 of the display device 704 depicting the view of the simulated environment.

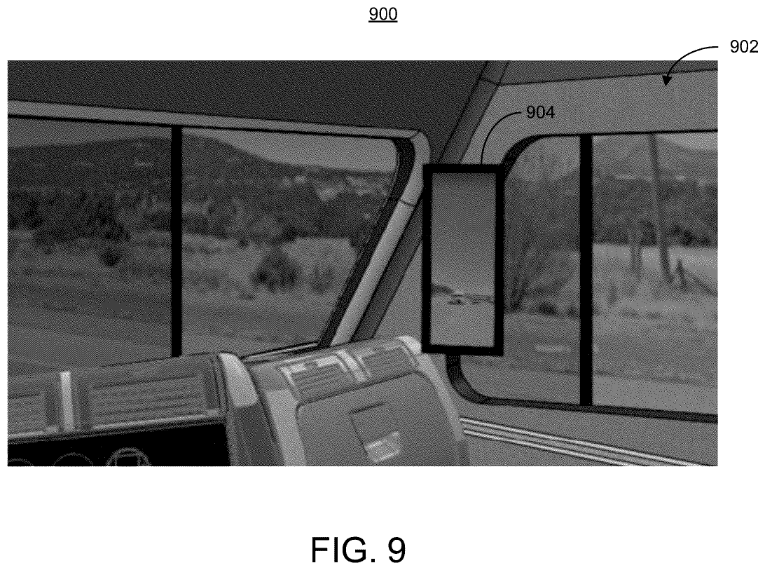

FIG. 9 is a perspective view 900 of the inside 902 of a cabin of an autonomous driving simulator, according to an embodiment. The cabin can be the same as or similar to the cabin 706. As illustrated in the perspective view 900 the inside 902 of the cabin can include a display 904. The display 904 can simulate a side mirror of a vehicle such that the display 904 can display behind the right side of the simulated vehicle of the autonomous driving simulator. A processor can generate the view of a simulated environment to be displayed on the display 904 based on the current position of a simulated vehicle within the simulated environment. The processor can transmit the generated view to the display 904.

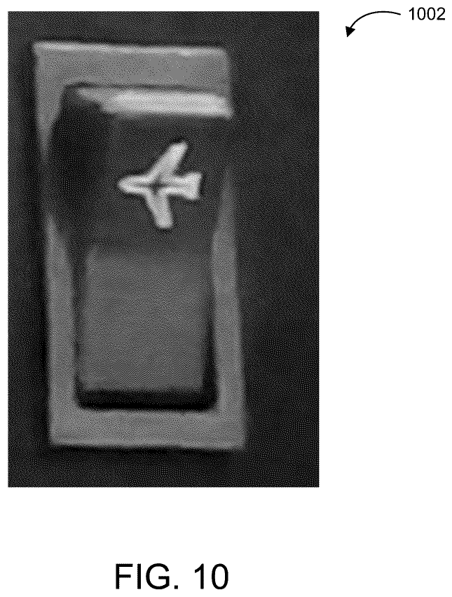

FIG. 10 depicts an overhead view switch 1002 of an autonomous driving simulator, according to an embodiment. The overhead view switch 1002 can enable an overhead view of a scenario to analyze perspectives during playback of a driving scenario. For example, as the autonomous driving simulator simulates a simulated vehicle driving through a simulated environment, the autonomous driving simulator can record the trajectories or actions of the simulated vehicle. The autonomous can record the trajectories or actions for sequential defined periods of time. Upon selection or changing a position of the overhead view switch 1002, a processor of the autonomous driving simulator can identify a most recently record period of time. The processor can analyze the recording, for example, to determine whether the user of the autonomous driving simulator drove the simulated vehicle within the simulated environment properly (e.g., within a defined time period) or took control of the simulated vehicle. Selecting the button can cause the processor to generate analytics based on the recording, such as the time it takes for the user to take control of the simulated vehicle, and display the analytics on the display device displaying the simulated environment.

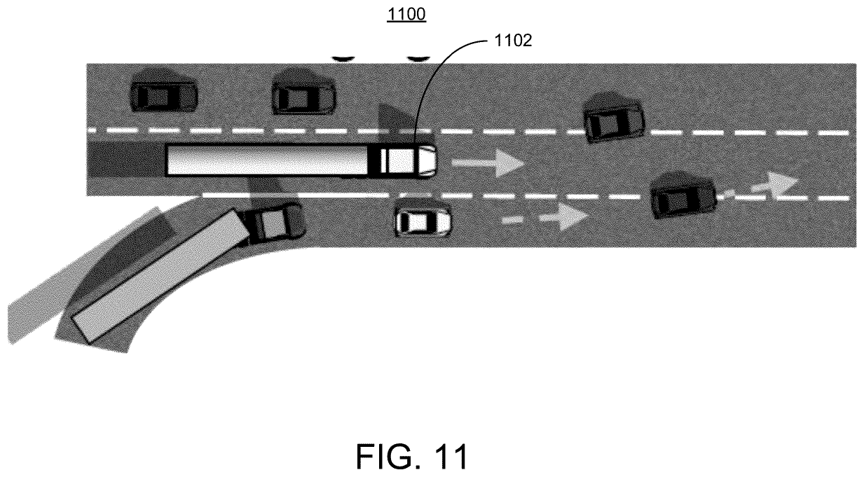

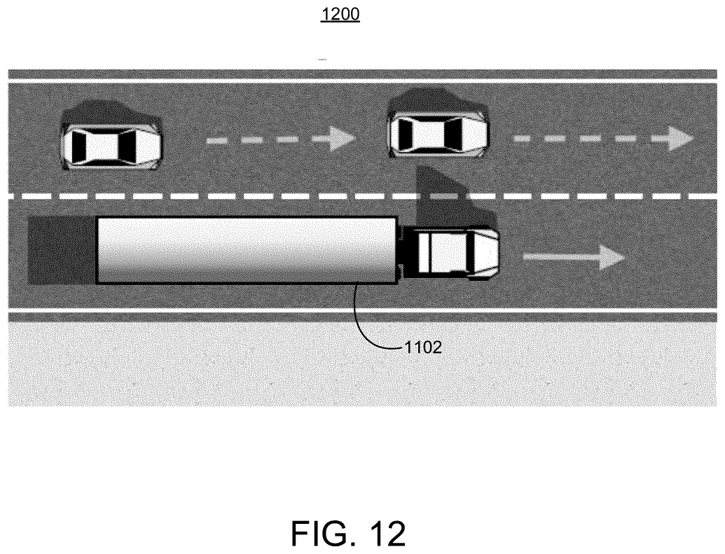

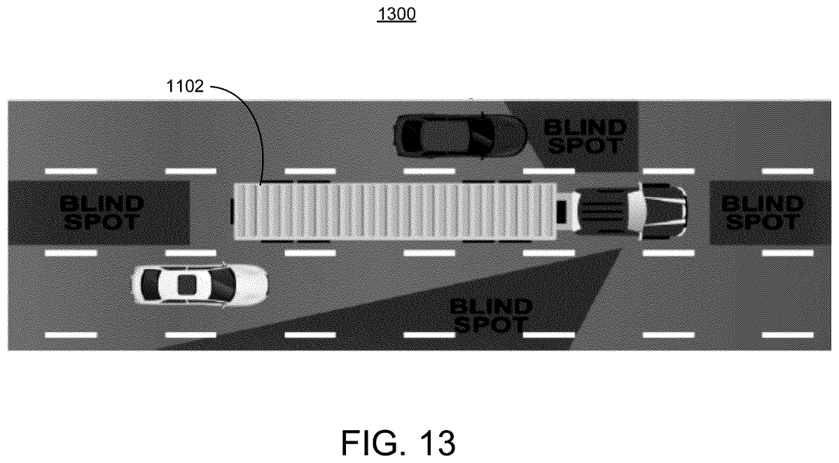

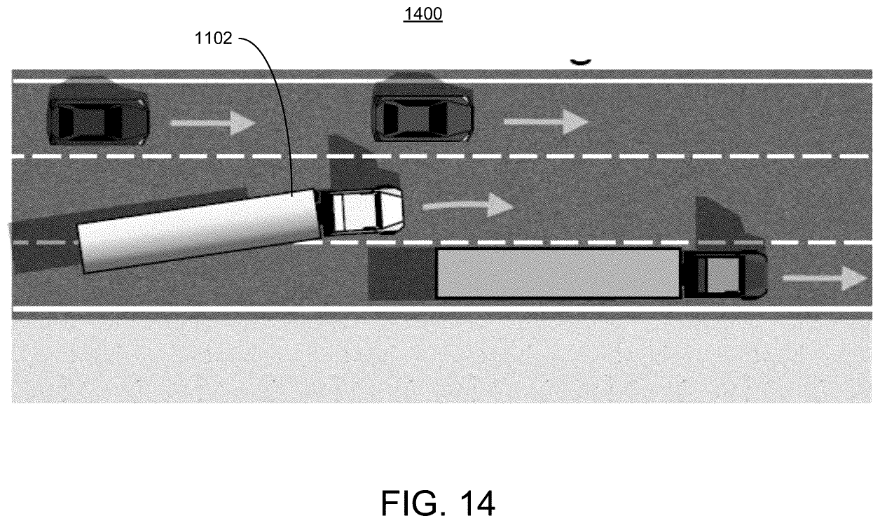

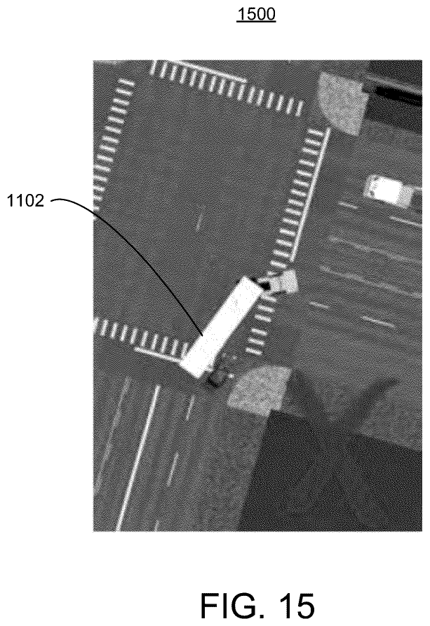

FIGS. 11-15 depict example training scenarios 1100-1500 of an autonomous driving simulator, according to an embodiment. The training scenarios 1100-1500 can each correspond to scenarios that a simulated vehicle may encounter in a simulated environment provided by the autonomous driving simulator (e.g., the driving simulator 102 or the driving simulator 202). As the simulated vehicle drives through the simulated environment, the autonomous driving simulator may trigger (e.g., initiate) a training scenario such as one of the training scenarios 1100-1500 to cause the simulated vehicle to encounter or otherwise go through the triggered training scenario. The autonomous driving simulator may trigger such a training scenario in response to the simulated vehicle reaching a defined location within the simulated environment. The autonomous driving simulator may trigger a training scenario in response to a user of a remote computing device (e.g., the remote computing device 106 or the remote device 204) selecting a training scenario from a user interface displayed at the remote computing device. The remote computing device may transmit an identification of the training scenario to the autonomous driving simulator to cause the autonomous driving simulator to trigger the training scenario identified by the identification. The simulated vehicle may go through such training scenarios in autonomous mode or manual mode. The user of the autonomous driving simulator can select the overhead view switch 1002 to cause the autonomous driving simulator to analyze a recording of the simulated vehicle traveling through the training scenario.

The training scenarios 1100-1500 may include different scenarios that a driver may face while driving in the real world. For example, the training scenario 1100 may be a scenario in which a simulated vehicle 1102 is traveling forward while a vehicle in another lane within the simulated environment merges in front of the simulated vehicle 1102. The training scenario 1200 can be a training scenario in which the simulated vehicle 1102 is driving in an adjacent lane (e.g., a lane that shares a lane line with another lane on the road) to a lane in which two other simulated vehicles are traveling in the same direction as the simulated vehicle 1102. The training scenario 1300 can be a training scenario in which the simulated vehicle 1102 has vehicles around the simulated vehicle 1102 between blind spots of the simulated vehicle 1102. The training scenario 1500 can be a training scenario in which the simulated vehicle 1102 turns a corner around another vehicle turning the same corner. Training scenarios can include any scenarios that drivers may face while driving on the road.

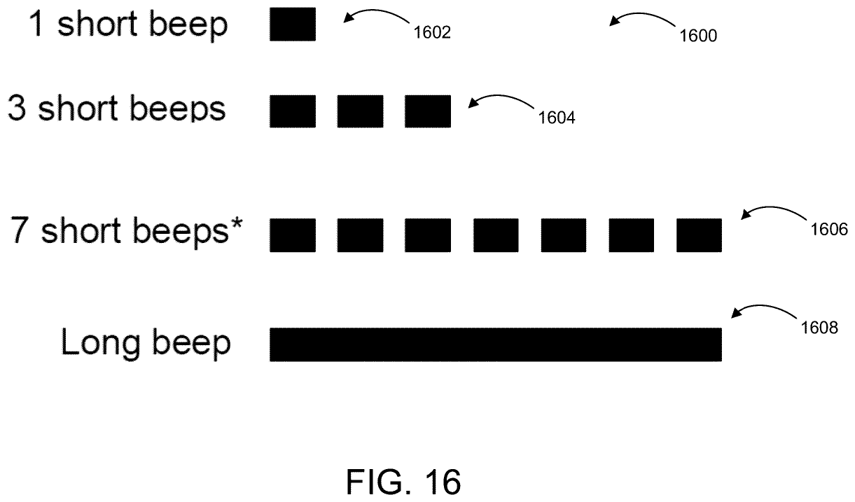

FIG. 16 depicts example audio signals 1600 of an autonomous driving simulator (e.g., the driving simulator 102 or the driving simulator 202), according to an embodiment. The audio signals 1600 can each correspond to different modes of operating a simulated vehicle (e.g., autonomous mode or manual mode). For example, the audio signal 1602 can be one short beep and indicate that a simulated vehicle within a simulated environment generated by the autonomous driving simulator is driving in autonomous mode. The audio signal 1604 can be three short beeps and indicate the simulated vehicle is driving in manual mode. The audio signal 1606 can be seven short beeps and indicate the mode in which the simulated vehicle is driving has transitioned from autonomous mode to manual mode. The audio signal can be one long (e.g., relative to the short beeps) beep and indicate an EMO button has been selected (e.g., that the mode in which the simulated vehicle is driving has transitioned from manual mode to autonomous mode).

The autonomous driving simulator may include a microphone or speaker that emits the audio signals 1600 upon detecting one of the events that correspond with the audio signals 1602-1606. In some cases, the autonomous driving simulator may emit a voice with words for different actions that the simulated vehicle takes. For example, the autonomous driving simulator may make the following announcements:
1. When initiating a lane change, the speaker may say “LEFT” or “RIGHT”;
2. When initiating a lane change and the lane change is canceled, the speaker may say “LANE CHANGE CANCEL”;
3. When approaching an intersection with a stoplight, the speaker may say “Stopping for Light” and “GOING THROUGH LIGHT”; and
4. When stopping in the middle of a lane, the speaker may say “STOPPING IN LANE.”
   The autonomous driving simulator may emit any words for any actions that the simulated vehicle takes within the simulated environment.

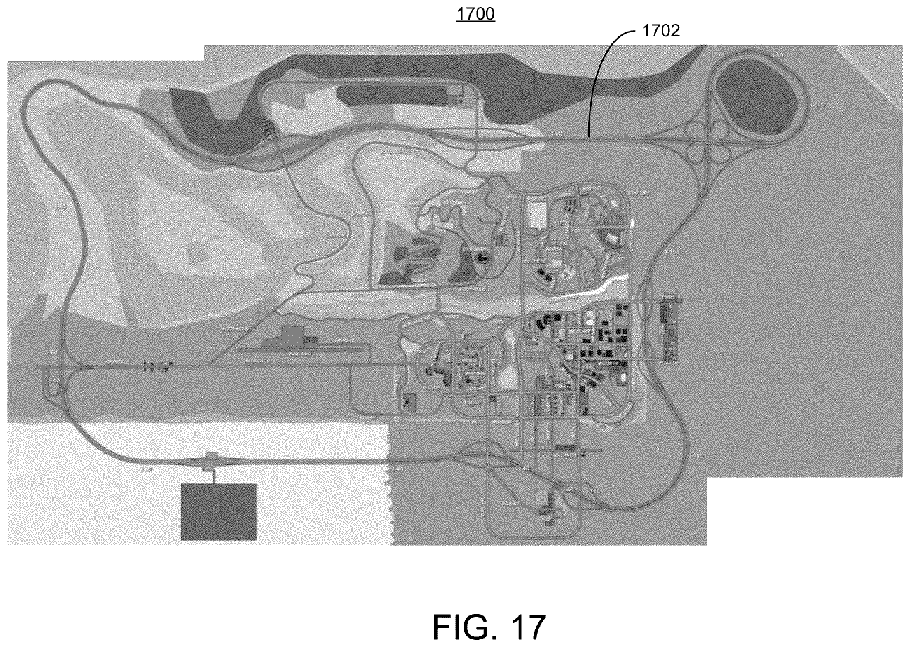

FIG. 17 depicts an overhead view of a simulated environment 1700 of an autonomous driving simulator, according to an embodiment. The simulated environment 1700 can be a three-dimensional environment in which one or more simulated vehicles can drive on roads and/or different terrains. For example, the simulated environment 1700 can include urban streets, rural streets, city streets, highway, and/or other terrains. The simulated environment 1700 may include a road 1702. The road 1702 may extend in different directions with one or more turns and/or intersections within the simulated environment 1700. The road 1702 and any other terrains can have slopes with different (e.g., a slope with a 6% grade). A simulated vehicle may travel on the road 1702 either according to predetermined paths or according to manual inputs, depending on the mode of the simulated vehicle (e.g., the mode of the application generating or maintaining the simulated environment and/or simulated vehicle).

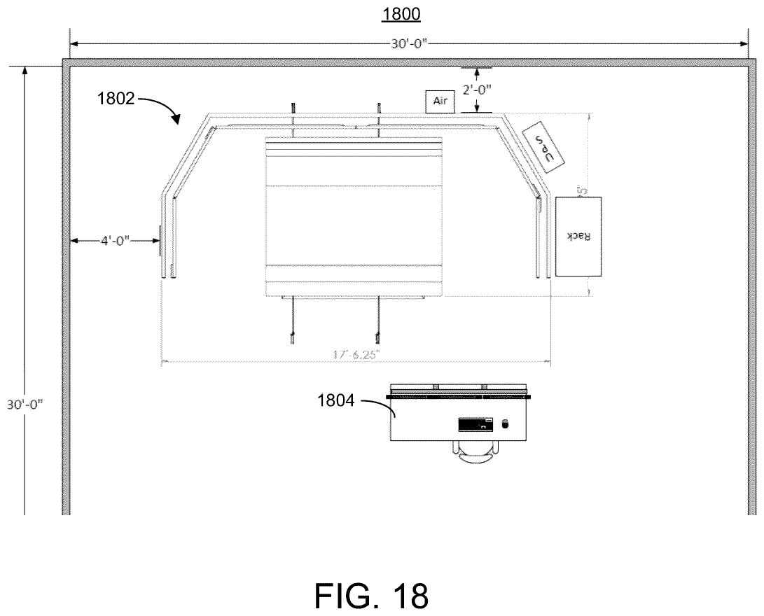

FIG. 18 depicts a plan view 1800 of a driving simulator 1802, according to an embodiment. In the plan view 1800, the driving simulator 1802 can be controlled by a remote computing device 1804. The driving simulator 1802 can be the same as or similar to the driving simulator 102 and/or the driving simulator 202. The remote computing device 1804 can be the same as or similar to the remote computing device 204. The remote computing device 1804 can transmit communication signals to the driving simulator 1802. In doing so, the remote computing device 1804 can transmit fault injections and/or training scenarios to the driving simulator 1802. The remote computing device 1804 can transmit signals to cause a simulated vehicle that the driving simulator 1802 has generated within a simulated environment to switch or transition between driving in autonomous mode to manual mode or from manual mode to autonomous mode. The remote computing device 1804 can transmit such signals in real-time as the driving simulator 1802 is simulating an autonomous vehicle driving within a simulated environment for a user accessing the driving simulator 1802. In some cases, the remote computing device 1804 can transmit such signals prior to the driving simulator 1802 performing a simulation and the driving simulator 1802 can store the signals in memory to implement during a subsequent simulation. Accordingly, using the remote computing device 1804, a trainer can either configure the simulated environment that the driving simulator 1802 generates for a simulation prior to the simulation or update the simulated environment or the simulation in real-time to train a user how to drive an autonomous vehicle.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various components, blocks, modules, circuits, and steps have been generally described in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of this disclosure or the claims.

Embodiments implemented in computer software may be implemented in software, firmware, middleware, microcode, hardware description languages, or any combination thereof. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the functions may be stored as one or more instructions or code on a non-transitory computer-readable or processor-readable storage medium. The steps of a method or algorithm disclosed herein may be embodied in a processor-executable software module, which may reside on a computer-readable or processor-readable storage medium. A non-transitory computer-readable or processor-readable media includes both computer storage media and tangible storage media that facilitate transfer of a computer program from one place to another. A non-transitory processor-readable storage media may be any available media that may be accessed by a computer. By way of example, and not limitation, such non-transitory processor-readable media may comprise RAM, ROM, EEPROM, CD-ROM or other optical disk storage, magnetic disk storage or other magnetic storage devices, or any other tangible storage medium that may be used to store desired program code in the form of instructions or data structures and that may be accessed by a computer or processor. Disk and disc, as used herein, include compact disc (CD), laser disc, optical disc, digital versatile disc (DVD), floppy disk, and Blu-ray disc, where “disks” usually reproduce data magnetically, while “discs” reproduce data optically with lasers. Combinations of the above should also be included within the scope of computer-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A system, comprising:
a driving simulator, the driving simulator comprising:
one or more input devices corresponding to controls of a vehicle;
a display; and
one or more processors communicatively coupled with the one or more input devices and the display, the one or more processors configured to simulate, on the display, an autonomous vehicle driving through a simulated environment in a manual mode based on inputs from the one or more input devices, automatically in an autonomous mode, and transition between manual mode and autonomous mode; and
a remote computing device, the remote computing device configured to:
receive an input from a user interface displayed at the remote computing device during a simulation of the autonomous vehicle in the autonomous mode, the input causing a fault in the operation of the autonomous vehicle in the autonomous mode.

2. The system of claim 1, wherein the input comprises an identification of a type of fault, and wherein the fault in the operation of the autonomous vehicle corresponds to the type of fault.

3. The system of claim 2, wherein the type of fault is selected from a plurality of types of faults comprising one or more of the autonomous vehicle exceeding a speed limit applicable to the autonomous vehicle within the simulated environment, veering the autonomous vehicle off of a road within the simulated environment, or the autonomous vehicle suddenly breaking in on the road within the simulated environment.

4. The system of claim 1, wherein the one or more input devices comprise a steering wheel, and wherein the fault comprises a change in orientation of the steering wheel.

5. The system of claim 1, wherein the fault comprises an adjustment to a predetermined path based on which the autonomous vehicle is driving within the simulated environment.

6. The system of claim 1, wherein the remote computing device is configured to transmit an identification of the fault to the one or more processors, receipt of the identification by the one or more processors causing the fault in the operation of the autonomous vehicle.

7. The system of claim 1, wherein the driving simulator comprises a housing in the shape of a semi-trailer truck cabin,
wherein the one or more processors are stored within the housing, and
wherein the display is a display external to the housing.

8. The system of claim 1, wherein the remote device:
receives a second input indicating a training scenario; and
adjusts the simulated environment based on the training scenario.

9. The system of claim 8, wherein the remote device:
transmits an identification of the training scenario; and
wherein the driving simulator executes a set of code corresponding to the training scenario based on the identification of the training scenario.

10. The system of claim 8, wherein the training scenario comprises a second simulated vehicle driving in front of the autonomous vehicle within the simulated environment.

11. The system of claim 1, wherein the driving simulator comprises:
a housing in the shape of a semi-trailer truck cabin,
wherein the one or more processors are stored within the housing.

12. The system of claim 11, further comprising:
a display device,
wherein the display device surrounds the housing, and
wherein the one or more processors transmit a view of the simulation to the display device.

13. A method, comprising:
simulating, by a processor on a display, an autonomous vehicle driving through a simulated environment in a manual mode based on inputs from one or more input devices corresponding to controls of a vehicle, automatically in an autonomous mode, and transition between manual mode and autonomous mode; and
receiving, by a remote processor, an input from a user interface displayed by the remote processor during a simulation of the autonomous vehicle in the autonomous mode, the input causing a fault in the operation of the autonomous vehicle in the autonomous mode.

14. The method of claim 13, wherein the input comprises an identification of a type of fault, and wherein the fault in the operation of the autonomous vehicle corresponds to the type of fault.

15. The method of claim 14, wherein the type of fault is selected from a plurality of types of faults comprising one or more of the autonomous vehicle exceeding a speed limit applicable to the autonomous vehicle within the simulated environment, veering the autonomous vehicle off of a road within the simulated environment, or the autonomous vehicle suddenly breaking in on the road within the simulated environment.

16. The method of claim 13, wherein the one or more input devices comprise a steering wheel, and wherein the fault comprises a change in orientation of the steering wheel.

17. The method of claim 13, wherein the fault comprises an adjustment to a predetermined path based on which the autonomous vehicle is driving within the simulated environment.

18. The method of claim 13, comprising:
transmitting, by the remote processor, an identification of the fault; and
responsive to receiving the identification of the fault, causing, by the processor, the fault in the operation of the autonomous vehicle.

19. The method of claim 13, comprising:
receiving, by the remote processor, a second input indicating a training scenario; and
adjusting, by the processor, the simulated environment based on the training scenario.

20. The method of claim 19, comprising:
transmitting, by the remote processor, an identification of the training scenario; and
executing, by the processor, a set of code corresponding to the training scenario based on the identification of the training scenario.
